(19) United States
(12) Patent Application Publication
(10) Pub. No.: US 2022/0297258 A1
(43) Pub. Date: Sep. 22, 2022

(54) SUBSTRATE POLISHING SIMULTANEOUSLY OVER MULTIPLE MINI PLATENS

(71) Applicant: Applied Materials, Inc., Santa Clara, CA (US)

(72) Inventors: Jeonghoon OH, Saratoga, CA (US); Steven M. ZUNIGA, Soquel, CA (US)

(21) Appl. No.: 17/204,832

(22) Filed: Mar. 17, 2021

(51) Int. Cl. B24B 37/30; B24B 37/04; B24B 37/10; H01L 21/321; H01L 21/768

(52) U.S. Cl. CPC B24B 37/30; B24B 37/042; B24B 37/105; H01L 21/3212; H01L 21/7684

(57) ABSTRACT

A substrate polishing apparatus includes a processing station including a plurality of polishing platens having a polishing pad thereon, and a substrate support configured to hold a substrate therein, wherein the substrate support is positionable to simultaneously position a substrate supported therein against polishing pads on at least two of the plurality of polishing platens. The processing station can form a standalone polishing system, or be one of at least two processing statins in a polishing tool, where at least one other polishing station includes a polishing platen to support a polishing pad thereon.

### BACKGROUND

### Description of the Related Art

Aspects of the invention generally relate to the fabrication of semiconductor devices and to chemical mechanical polishing and planarization of semiconductor devices.

### Field

One method for forming vertical and horizontal interconnects employs the damascene or dual damascene method. In the damascene method, one or more dielectric materials, such as a low k dielectric material, are deposited and pattern etched to form vertical interconnect openings therein or therethrough, i.e., visa or contact openings, and horizontal interconnect openings, i.e., lines. Conductive materials, such as copper-containing materials, and other materials, such as barrier layer materials used to prevent diffusion of copper-containing materials into the surrounding low k dielectric, are then deposited into the etched openings, as well as undesirably over the upper surface or field of the patterned dielectric material. Any excess copper-containing materials and excess barrier layer material external to the etched pattern, such as that on the field of the dielectric layer on the substrate, is then removed.

As layers of dielectric, barrier and conductive materials are sequentially deposited on the substrate and at least in part removed, the uppermost surface of the substrate may become non-planar across its surface and require planarization. Planar zing a surface, or “polishing” a surface, is a process where material is removed from the surface of the substrate to form a generally flat, even, planar surface. Planarization is useful in dual damascene processes to remove excess material deposited on the field, and to provide a flat planar surface for subsequent levels of metallization thereover and processing thereof. Planarization may also be used in removing undesired surface topography and surface defects, such as rough surfaces, agglomerated materials, crystal lattice damage, scratches, and contaminated layers or materials.

Chemical mechanical planarization, or chemical mechanical polishing (CMP), is a common technique used to planarize substrates. In conventional CMP techniques, a substrate carrier or polishing head is mounted on a carrier assembly and positionable in contact with a polishing article, commonly known as a polishing pad, in a CMP apparatus. The substrate to be polished is mounted to the polishing head. The carrier assembly provides a controllable pressure to the substrate urging the substrate against the polishing article. The polishing article, for example a polishing pad, is moved relative to the substrate by an external driving force, commonly about the center of the large area of the pad facing the substrate. A liquid, often including an abrasive therein, is dispensed onto the pad to be transported to the interface between the facing surfaces of the pad and substrate. This material is commonly called slurry, and often includes a chemical agent to modify the material being polished and an abrasive to erode the modified material off of the substrate. Thus, the CMP apparatus effects polishing or rubbing movement between the surface of the substrate and the polishing article while dispersing a polishing composition, known as a slurry, to effect both chemical activity and mechanical activity to remove a material from the substrate.

Conventionally, to polish copper features, such as dual damascene features where copper is present in an opening in a dielectric layer and also extends over the field thereof, the copper-containing material, and a portion of the barrier layer deposited into the opening and onto the field prior to the deposition of the copper material, is polished to the level of the barrier layer, and then the barrier layer is polished, with a portion of the dielectric layer and copper features, to a level of the underlying dielectric layer using abrasive polishing solutions. However, such a polishing process often results in uneven removal of copper in via and line features and the dielectric layer resulting in the formation of topographical defects, such as concavities or depressions in the features, referred to as dishing, and removal of dielectric material surrounding features, referred to as erosion.

### SUMMARY

In one aspect, a substrate polishing apparatus includes a processing station having a plurality of polishing platens each having a polishing pad thereon, and a substrate support configured to hold a substrate therein, wherein the substrate support is positionable to simultaneously position a substrate supported therein against polishing pads on at least two of the plurality of polishing platens.

In another aspect, a method for substrate polishing is provided, and includes positioning a substrate within a polishing station having a plurality of polishing platens each having a polishing pad thereon, the polishing platens and a substrate support configured to hold a substrate therein, positioning the substrate support to position a substrate supported therein against polishing pads on at least two of the plurality of polishing platens simultaneously, and polishing the substrate simultaneously on the two polishing pads.

In another aspect, a polishing apparatus includes a first polishing station, a second polishing station, and a substrate support configured to support a substrate therein in facing relationship to a polishing station and moveable to position a substrate supported therein at the first polishing station and the second polishing station and at least a first and a second rotatable polishing platen are disposed in one of the first polishing station and the second polishing station and configured to support a polishing pad thereon, the substrate support positionable to engage a substrate supported therein against a polishing pad on the first polishing platen and simultaneously against a polishing pad on the second polishing platen.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is an isometric view of an exemplary polishing apparatus hereof.

FIG. 1B depicts one embodiment of a chemical mechanical polishing system having an interface for loading and unloading of substrates with respect thereto.

FIG. 2 is an exploded view of a portion of the polishing apparatus of FIG. 1.

FIG. 3 is a plane view of a polishing station of the polishing apparatus of FIG. 1.

FIGS. 4A to 4C are schematic representations of exemplary substrate motions with respect to a plurality of polishing pads, for example the plurality of polishing pads in a single polishing station of FIG. 3.

FIG. 5 is a flowchart setting forth activities useful for polishing a substrate.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

In general, aspects of the invention provide methods and apparatus for polishing substrates while reducing dishing of the substrate surface and essentially having no remaining residues. The invention will be described below in reference to a planarizing process for the removal of conductive materials, such as copper-containing materials and barrier layer materials, such as tantalum and tantalum nitride, from a substrate surface by chemical mechanical polishing (CMP) techniques using a polishing media including for example a polishing pad and a slurry. Chemical mechanical polishing is broadly defined herein as polishing a substrate by a combination of both chemical and mechanical activity.

The planarization process herein can be carried out using chemical mechanical polishing process equipment, such as the Mirra® CMP System available from Applied Materials, Inc., of Santa Clara, Calif., as shown and described in U.S. Pat. No. 6,780,773 entitled, “Method of chemical mechanical polishing with high throughput and low dishing,” the entirety of which is incorporated herein by reference to the extent not inconsistent with the invention. Although, the CMP process and composition are illustrated utilizing the Mirra® CMP System, any system enabling polishing using the methods described herein, such as the Reflexion™ CMP System available from Applied Materials, Inc., of Santa Clara, Calif., can be used to advantage. The following apparatus description is illustrative and should not be construed or interpreted as limiting the scope of the invention.

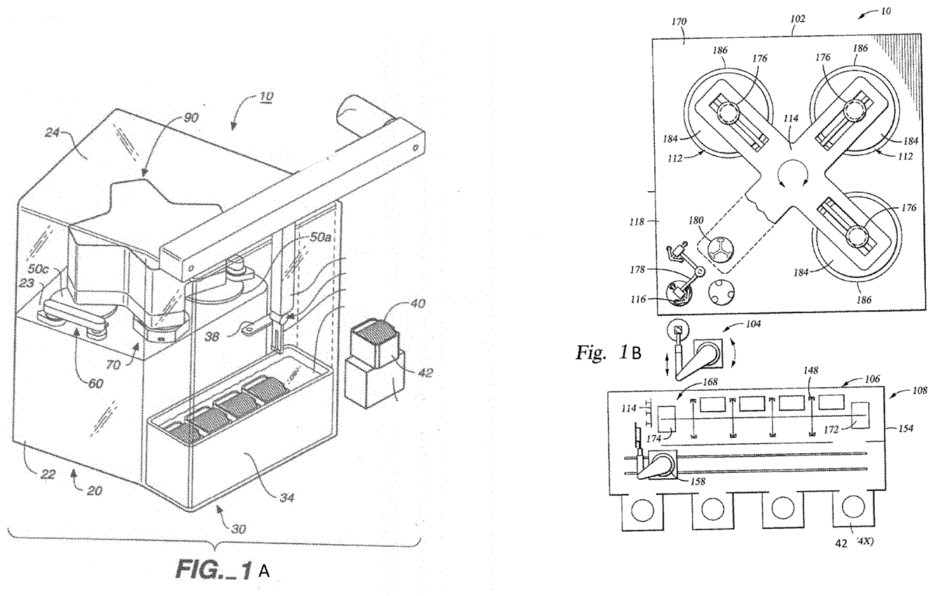

FIG. 1 shows a perspective view of a polishing system. The polishing system 10 includes a polishing apparatus 20 adjacent to a substrate loading apparatus 30. Substrates 40 are brought to the system 10 in a cassette 42, which is immediately stored in a tub 34 so as to keep the substrates wet. The substrates 40 are individually loaded from the cassette 42 into the substrate polishing apparatus 20, which polishes them and then returns them to the original cassette 42 or another one in the tub 34. The figure does not show a wall interposed between the polishing apparatus 20 and the substrate loading apparatus 30 so as to contain the slurry and other polishing debris within polishing apparatus 20 and away from the tub 34. An unillustrated sliding door in the wall is opened for transfer of substrates between the two apparatus 20 and 30. The wall may act as the barrier between the clean room containing the substrate loading apparatus 30 and a dirtier area containing the polishing apparatus 20.

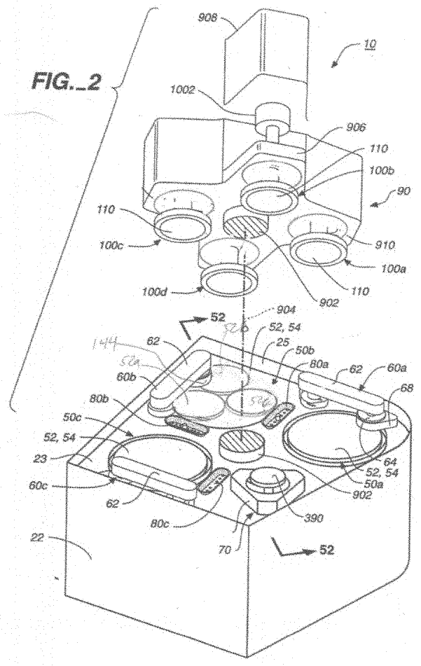

The polishing apparatus 20 includes a lower machine base 22 with a table top 23 mounted thereon and a removable upper outer cover 24 surrounding a series of polishing stations 50a, 50b, and 50c. As shown in the exploded isometric view of FIG. 2, a weir or fence 25 surrounds the table top 23 to contain the liquids and slurry being thrown about and which are drained through unillustrated drains in the table top.

Each polishing station 50a, 50b, or 50c includes at least one rotatable platen 52 on which is placed a polishing pad 54, and it further includes an associated pad conditioner apparatus 60a, 60b, or 60c, each with a rotatable arm 62 holding a conditioner head 64 and an associated washing basin 68 for the conditioner head 64. Polishing station 50b here includes at least two rotatable polishing platens, here three, platens 52a, 52b and 52c. The polishing pad receiving surfaces of the platens 52a-c are coplanar, or the polishing surfaces of the polishing pads 54a-c thereon are coplanar, to allow a substrate 40 to be simultaneously polished on more than one polishing pad at a time, for example any two or all three of the polishing pads 54a-c simultaneously. The surface area of the polishing pads 54a-c facing a substrate 40 are each as large or larger than the surface area of the surface of the substrate to be polished. The base 22 also supports a transfer station 70 positioned in a square arrangement with the three polishing stations 50a, 50b, and 50c. The transfer station 70 serves multiple functions of receiving individual substrates 40 from the loading apparatus 30, possibly rinsing them, loading them to substrate heads (to be described later) which hold them during polishing, receiving the substrates 40 back from the substrate heads, washing them, and finally transferring them back to the loading apparatus 30. It also washes the substrate head after its substrate has been unloaded.

Two intermediate washing stations 80a and 80b are located between neighboring ones of the polishing stations 50a, 50b, and 50c, and a third washing station 80c may be located between the last polishing station 50c and the transfer station 70. These rinse a substrate 40 as it passes from one polishing station to another and to the transfer station 70 and may effectively buff the substrate 40 as well.

A rotatable multi-head carousel 90, which includes four substrate head systems 100a, 100b, 100c, and 100d each of which receives and holds a substrate 40 and supports them to polish them by pressing them against respective polishing pads 54 held on the platens 52 at the respective polishing stations 50a, 50b, and 50c. The carousel 90, which is in the shape of a cross because the areas between its arms are removed, is supported on a stationary center post 902 and is rotated thereon about a carousel axis 904 by a motor assembly located within the base 22.

In this configuration according to the invention, the four identical substrate head systems 100a, 100b, 100c, and 100d are mounted on a carousel support plate 906 at equal angular intervals about the carousel axis 904. The center post 902 centrally supports the carousel support plate 906 and allows the carousel motor to rotate the carousel support plate 906, the substrate head systems 100a, 100b, 100c, and 100d, and the substrates 40 attached thereto about the carousel axis 904.

Each substrate head system 100a, 100b, 100c, or 100d includes a substrate head 110 that is rotated about its own axis by a head-rotation motor 1002 connected to it by a shaft. The heads 110 can rotate independently as driven by their dedicated head-rotation motors 1002 (shown in FIG. 2 by the removal of one carousel quarter-cover 908), and can further independently oscillate radially, i.e., linearly, or orbit around a center point of the slots 910 formed in the carousel support plate 906, while simultaneously rotating. Here, the slots 910 are circular openings, which allows the polishing head to move in an orbital path, for example an epicyclical or other path, and thus move the substrate pressed against a polishing pad in that same path, or alternately in a linear, radial direction of the polishing pad 54, path. Raising or lowering substrates attached to the bottom of the substrate heads 110 is performed within the substrate head systems 100. An advantage of the overall carousel system is that very little vertical stroke is required of the substrate head 110 to accept the substrates and position them for polishing and washing. What little vertical stroke is required can be accommodated within the lowermost member at the very end of the substrate head 110. An input control signal causes relative motion (extension and retraction of the head) between a substrate head lower member which includes a substrate receiving recess and a vertical stationary substrate head upper member according to an input control signal (e.g., a pneumatic, hydraulic, or electrical signal).

During the actual polishing of a substrate, the substrate heads 110 of three of the substrate head systems, e.g., 100a, 100b, and 100c, are positioned at and above respective polishing stations 50a, 50b, and 50c, each polishing station 50a, 50b and 50c having one or more independently rotatable platens 52 each supporting a polishing pad 54 whose surface is wetted, for example with an abrasive slurry where the polishing station is used for material removal, or with a buffing composition which need not include particulate abrasives therein, which acts as the media for polishing the substrate 40. During polishing, the substrate head systems 100a, 100b, and 100c independently oscillate along respective radii of the carousel 90 so that the associated substrate heads 110 move along a diameter of a respective polishing pad 54. In a typical process, the linear sweep axis of a substrate head 110 is aligned to the center of the polishing pad 54. Additionally, here, the polishing heads can be oscillated over the rotating platens 52 at a polishing station 50.

In use, the substrate head 110, for example, that of the fourth substrate head system 100d, is initially positioned above the substrate transfer station 70. When the carousel 90 is rotated, it positions different substrate head systems 100a, 100b, 100c, and 100d over the polishing stations 50a, 50b, and 50c and over the transfer station 70. The carousel 90 allows each substrate head system 1100 to be sequentially located first over the transfer station 70, then over one or more of the polishing stations 50, and then back to the transfer station 70.

Each polishing pad 54 can be continuously or periodically conditioned by one of the pad conditioner apparatus 60, each having an independently rotating conditioner head 64 attached to the conditioner arm 62. An abrasive conditioning plate or a similar conditioning surface needs to be included at the bottom of the conditioner head 64. The arm 62 sweeps the conditioner head 64 across the associated polishing pad 54 in an oscillatory motion generally between the center of the polishing pad 54 and its perimeter. The conditioner head 64 is pressed against the pad 54 to abrade and condition the pad so that it thereafter effectively polishes any substrate 40 pressed against it while it is rotating.

Here, at least the polishing station 50b includes a plurality of rotatable platens 52a, 52b and 52c, each having polishing media such as a polishing pad 54, disposed thereon. The polishing pad 54 is a polishing pad having a durable roughened surface typically composed of microporous polyurethane or polyurethane mixed with filler. Polishing pads 54 may be embossed or stamped with a pattern to improve distribution of a slurry 9 across the face of the substrate 40. Polishing pads 54 may include a hard polishing material, a soft polishing material, or combinations thereof, as well as other material properties.

A hard polishing material is broadly described herein as a polishing material having a polishing surface of a hardness of about 50 or greater on the Shore D Hardness Scale for polymeric materials as described and measured by the American Society for Testing and Materials (ASTM), headquartered in Philadelphia, Pa. A suitable hard polishing material is a material comprising the IC-1000, IC-1010, and the IC-1400 polishing pads available from Rodel Inc., of Phoenix, Ariz. (IC-1000 is a product name of Rodel, Inc.)

The polishing pads 54 may also include composite pads of one or more layers, with a surface layer having a hardness of about 50 or greater on the Shore D Hardness Scale. The composite pads may have an overall hardness of less than about 50 on the Shore D Hardness Scale. While the description herein describes the use of the IC series of pads from Rodel Inc., the invention is equally applicable to all polishing pads having the hardness described herein.

A hard polishing material is broadly described herein as a polishing material having a polishing surface of a hardness of less than about 50 on the Shore D Hardness Scale for polymeric materials as described and measured by the American Society for Testing and Materials (ASTM), headquartered in Philadelphia, Pa. The soft polishing pad may be composed of a napped poromeric synthetic material, such as a uniformly compressible material including a polymeric material, i.e., plastic, and/or foam, felt, rubber, or a combination thereof. An example of a soft polishing material is polyurethane impregnated with felt. An example of a soft polishing pad is the Politex or Suba series, ie., Suba IV, of polishing pads available from Rodel, Inc. (Politex and Suba are tradenames of Rodel, Inc.)

Alternatively, polishing pads 54 may be a standard two-layer pad in which the upper layer has a durable roughened surface and is harder than the lower layer. For example, the upper layer of the two-layer pad may be composed of microporous polyurethane or polyurethane mixed with filler, whereas the lower layer maybe composed of compressed felt fibers leached with urethane. Both the upper and lower layers may be approximately fifty mils thick. A two-layer standard pad, with the upper layer composed of IC-1000 and the lower layer composed of SUBA-4, is available from Rodel (IC-1000 and SUBA-4 are product names of Rodel, Inc.).

In one embodiment of the apparatus, the polishing station 50b includes the first second and third platens 52a-c, and has a first, second, and third polishing pad 54a-c disposed thereon, respectively. Each of the polishing pads 54a-c may be adapted for a unique function. For example, the first polishing pad 54a may have properties, for example a stiffness or hardness necessary to remove bulk copper-containing material disposed on the field of the substrate 40. The second polishing pad 54b may have a second hardness or stiffness for, and the platen 52b and associated pad 54b is adapted for polishing a substrate 40 to remove residual copper-containing material disposed on the substrate 40 as well as a barrier material. A third polishing pad being a relatively softer polishing pad useful for a barrier removal process, such as removing a tantalum containing material, e.g., tantalum and tantalum nitride, on the substrate 40 and dielectric layer buffing following the two-step copper removal process. May be used as the third polishing pad 54c on platen 52c. Additionally, for example, the polishing pads 54a and 54b may have the same material properties, for example to remove residual metal such as copper and the underlying barrier material, and the third polishing pad 54c is provided having different material properties to remove residual barrier layer material and buff the dielectric layer. Here, at least two different platens 52 are deployed at the second polishing station 50b, having a first pad on a first platen 52a therein having material properties different than the material properties of a second pad 54b on a second platen 52b therein. Additionally, different slurries may be applied to the different ones of the polishing pads 54a-c. For example, where the polishing station 50b is used to clear an overlying metal and remove the underlying barrier layer where the overlying metal was previously polished to reveal at least a portion of the underlying barrier layer, a slurry selective to convert the barrier layer to a more easily removed material can be employed on one of the polishing pads, for example where the polishing station has three pads, the second pad 54b, and a different chemical composition, such as deionized water and a wetting composition, applied to the third pad where buffing is performed. Where the primary purpose of the first pad 54a is to remove copper, a slurry selective to copper is distributed to that pad 54a. Additionally, where three pads are used, two of the pads may have the same composition, and the third a different composition. Here, the same or a different slurry composition can be applied to two of the pads 54a, b in the multi-pad station 50b, and a different chemistry, which may or may not include an abrasive, applied to the third pad 54c of a different composition.

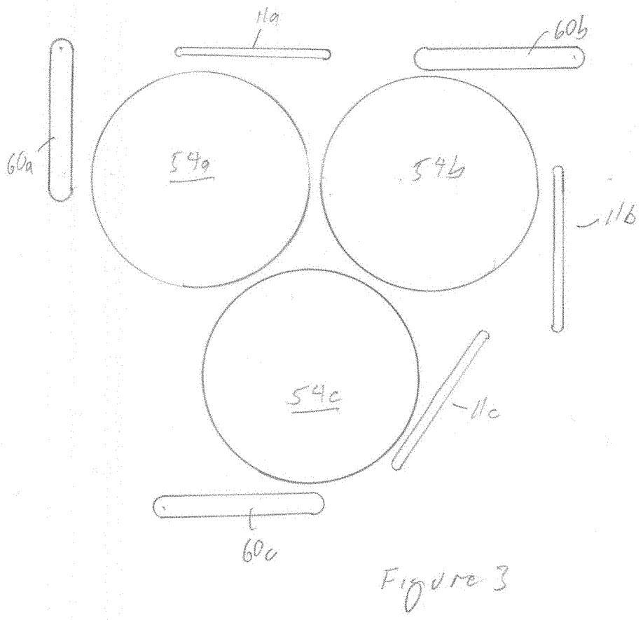

Each of the platens 52 may be a rotatable aluminum or stainless steel platen connected to a platen drive motor (not shown). Each of the polishing stations 50a-c may include a pad conditioner apparatus 60, whereas polishing station 50b includes a pad conditioning apparatus for each platen thereof. The pad conditioner apparatuses 60 have an arm 62 holding an independently rotating conditioner head 64 and an associated washing basin (not shown). The pad conditioner apparatuses 60a-c maintain the condition of the polishing pad so that it will effectively polish the substrates 40. Each of the polishing platens 52a-c of polishing station 50b may be served by a different conditioner apparatus 60, configured to condition the type of pad being used on that platen 52a-c, as is shown in FIG. 3.

Herein FIG. 3, in contrast to FIG. 2, each platen 52/pad 54 has dedicated thereto a conditioner, here conditioners 60a, 60b and 60c, configured to condition a corresponding one of the pads 54a, 54b and 54c, as well as a dedicated rinse arms 11a, 11b and 11c as discussed further herein. The polishing stations 50a-c each have dedicated composition delivery/rinse arms 11 associated therewith that includes two or more supply tubes to provide one or more CMP compositions, cleaning compositions, and/or water to the surface of the polishing media. FIG. 3 shows an arrangement of delivery arms for station 50b. The composition delivery/rinse arm 11 delivers the one or more liquid compositions to the center of the rotating pad 54 in amounts sufficient to cover and wet the entire polishing media. Each composition delivery/rinse arm 11 also includes several spray nozzles (not shown) that can provide a high-pressure fluid rinse on to the polishing article at the end of each polishing and conditioning cycle. In polishing station 50b, three different composition delivery/rinse arms 11 associated therewith, the arm 11a associated with platen 52a, the arm 11b associated with platen 52b, and the arm 11c associated with platen 52c. Different chemical or rinse compositions, including slurries carrying an abrasive particle in addition to the fluid chemistry thereof, are deliverable through the arms 11a-c, selected for the composition of the respective pad 54a-c onto which they are dispensed and the process to be performed on the substrate 40 using that pad 54a-c, as discussed previously herein.

The polishing heads 100 perform several mechanical functions. Generally, the polishing head 100 holds the substrate 40 against the polishing pads 54, to distribute a downward pressure across the back surface of the substrate 1, rotates the substrate 40 while it is in contact with a polishing pad 54, and ensures that the substrate 40 does not slip out from beneath the polishing head 100 during polishing thereof or between polishing stations 50a-c and the load/unload station 70.

FIG. 1B illustrates a simplified plan view of an alternative embodiment to FIG. 1A. In this embodiment the system 10 generally includes a polisher 102, a transfer robot 104 and a factory interface 108. A post-CMP treatment module 168 is typically disposed within the factory interface 108. The post-CMP treatment module 168 generally includes an annealing station 172 and a deposition station 174. The annealing station 172 and the deposition station 174 may be positioned adjacent each other, in a space-apart relation, or in different areas within the system 10. The post-CMP treatment module 168 may additionally include a cleaner 106. One example of a polishing system that may be adapted to benefit from the invention includes a MIRRA MESA™ CMP system, available from Applied Materials, Inc., of Santa Clara, Calif. A description of the MIRRA MESA™ CMP system is disclosed in commonly-assigned U.S. patent application Ser. No. 09/547,189, filed on May 11, 2000 now U.S. Pat. No. 6,361,422 by Ettinger et al., which is incorporated herein by reference in its entirety. Although the post-CMP treatment module 168 is shown disposed in the factory interface 108 as an integral component in the chemical mechanical polishing system 100 described with reference to FIG. 1A, the invention has utility in other polishing systems that both polish substrates and deposit a metal-containing layer thereon, including systems that anneal the metal-containing layer before and/or after polishing.

In one embodiment, the factory interface 108 includes a plurality of substrate cassettes 42, at least one or more interface robots 158, an input module 144 and the post-CMP treatment module 168. The factory interface robot 158 generally provides the range of motion required to transfer substrates between the cassettes 42 and other modules (i.e., the input module 144 and the post-CMP treatment module 168) of the system 10. Examples of a robot that may be utilized as the factory interface robot 158 are a 4-Link robot, manufactured by Kensington Laboratories, Inc., of Richmond, Calif. and a model Equipe 407B, manufactured by PRI Automation, of Billerica, Mass.

Unprocessed substrates are generally transferred from the cassettes 42 to the input module 144 by the interface robot 158. The input module 144 generally facilitates transfer of the substrate between the interface robot 158 and the transfer robot 104. The transfer robot 104 transfers the substrate between the input module 144 and the polisher 102. Processed substrates are generally returned to cassettes 42 disposed in the factory interface 108 in the reverse manner.

The transfer robot 104 may be any number of robots utilized to transfer substrates in a CMP environment. Generally, the transfer robot 104 is substantially similar to the factory interface robot 108.

The polisher 102 generally comprises a base 170, a transfer station 118, one or more polishing heads 176, a CMP robot 114 and one or more polishing stations 112. The transfer station 118 is disposed on the base 170 and generally includes a robot interface 116, transfer station robot 178 and a load cup 180. The robot interface 116 is configured to accept the substrate from the transfer robot 104. The transfer station robot 178 transfers the substrate between the robot interface 116 and the load cup 180. The load cup 180 generally transfers the substrate to the polishing head 176 that retains the substrate during polishing. One load cup 180 that may be adapted to benefit from the invention is described in U.S. patent application Ser. No. 09/414,907, filed on Oct. 8, 1999 now U.S. Pat. No. 6,716,086 by Tobin, which is incorporated by reference herein in its entirety. One transfer station 118 that may be adapted to benefit from the invention is described in U.S. Pat. No. 6,156,124, issued Dec. 5, 2000 to Tobin, which is also incorporated by reference herein in its entirety.

The CMP robot 114 is generally coupled to the base 170 and supports the polishing head 176 respectively on a plurality of arms 182 extending from the transfer station robot 178. The CMP robot 114 may be indexed so that each polishing head 176 may be positioned above the load cup 180 to facilitate substrate transfer therewith and positioned over one of the polishing stations 112 to facilitate substrate polishing.

The polishing head 176 generally retains the substrate during transfer between the polishing stations 112 and the transfer station 118 and during processing. The polishing head 176 moves axially to press the substrate against a polishing material 184 disposed in the polishing station 112 during processing. Polishing the substrate is generally accomplished by moving the substrate while retained in the polishing head 176 in a polishing motion relative to the polishing material 184 in the presence of a polishing fluid.

The polishing station 112 generally includes a platen 186 that supports the polishing material 184. In one embodiment, the platen 186 and polishing material 184 disposed thereon rotate to provide the polishing motion. It is understood that any polisher providing a relative polishing motion (including those not explicitly described herein) may alternatively be utilized. For example, the polishing material 184 may be moved under the polishing head 176 in a linear, x/y or orbital motion. The polishing head 176 may rotate, move linearly, orbit or move in other motions relative to the polishing material 184 that may be moving or stationary. Some exemplary polishers that may be adapted to benefit from the invention are described in U.S. Pat. No. 5,738,573, issued Aug. 14, 1998 to Tolles, et al., U.S. Provisional Patent Application No. 60/185,812, filed Feb. 29, 2000, by Sommer, and in U.S. patent application Ser. No. 09/244,456, filed Feb. 4, 1999 now U.S. Pat. No. 6,244,935 by Birang, et al., all of which are hereby incorporated by reference in their entirety. It should be noted that other polishers provided by other equipment manufacturers could be modified to incorporate aspects of the invention.

The polishing material 184 may be conventional or fixed abrasive material. Conventional polishing material 184 is generally comprised of a foamed polymer and disposed as a pad on the platen 186. In one embodiment, the conventional polishing material 184 is a foamed polyurethane. Such conventional polishing material 184 is available from Rodel Corporation, located in Newark, Del.

Fixed abrasive polishing material 184 is generally comprised of a plurality of abrasive particles suspended in a resin binder that is disposed in discrete elements on a backing sheet. Fixed abrasive polishing material 184 may be utilized in either pad or web form. As the abrasive particles are contained in the polishing material 184 itself, systems utilizing fixed abrasive polishing materials generally utilize polishing fluids that do not contain abrasives. Examples of fixed abrasive polishing material 184 are disclosed in U.S. Pat. No. 5,692,950, issued Dec. 2, 1997 to Rutherford et al., and U.S. Pat. No. 5,453,312, issued Sep. 26, 1995 to Haas et al, both of which are hereby incorporated by reference in their entireties. Such fixed abrasive material is additionally available from Minnesota Manufacturing and Mining Company (3M), located in Saint Paul, Minn.

In one embodiment, the post-CMP treatment module 168 is described as incorporating the cleaner 106 residing within the factory interface. However, the post-CMP treatment module 168 (or the annealing station 172) may alternatively “standalone” outside the system 10 or may be disposed proximate the polisher 102 in conjunction with other modules (i.e., the cleaning module, deposition station, and the like) either on the polisher 102 or in the factory interface 108.

The cleaner 106 generally removes polishing residue such as polishing fluid (i.e., slurry), abraded material (from substrate and/or the polishing material 184) and other contaminants from the polished substrate. In one embodiment, the cleaner 106 generally includes a walking beam 148 that transports processed substrates through in a cleaner 106 of the cleaner 106 having the deposition station 174 integrated therein. The walking beam 148, which comprises a series of substrate grippers (not shown) connected to a horizontal bar (not shown), transports polished substrates through cleaning and/or deposition baths in the cleaner 106. The substrate is washed and scrubbed with cleaning fluids as the substrate moves through the cleaner 106 on the walking beam 148. In at least one portion of the cleaner 106, the substrate is sprayed or immersed in a plating-mediating fluid such as a plating fluid to form the metal-containing layer on the substrate. The substrate is moved through the cleaner 106 towards an end 154 as the slurry and other contaminants which may have accumulated on the substrate during polishing or deposition are removed. At the end of the cleaning sequence, the cleaned substrate is removed from the walking beam 148 by the factory interface robot 158 and placed in the annealing station 172. After annealing, the substrate is retrieved from the annealing station 172 by the interface robot 158 and returned to one of the wafer storage cassettes 42. One cleaner that may be adapted to benefit from the invention is described in U.S. patent Ser. No. 09/558,815, filed on Apr. 26, 2000 now U.S. Pat. No. 6,575,177 by Brown, et al., which is incorporated by reference herein in its entirety.

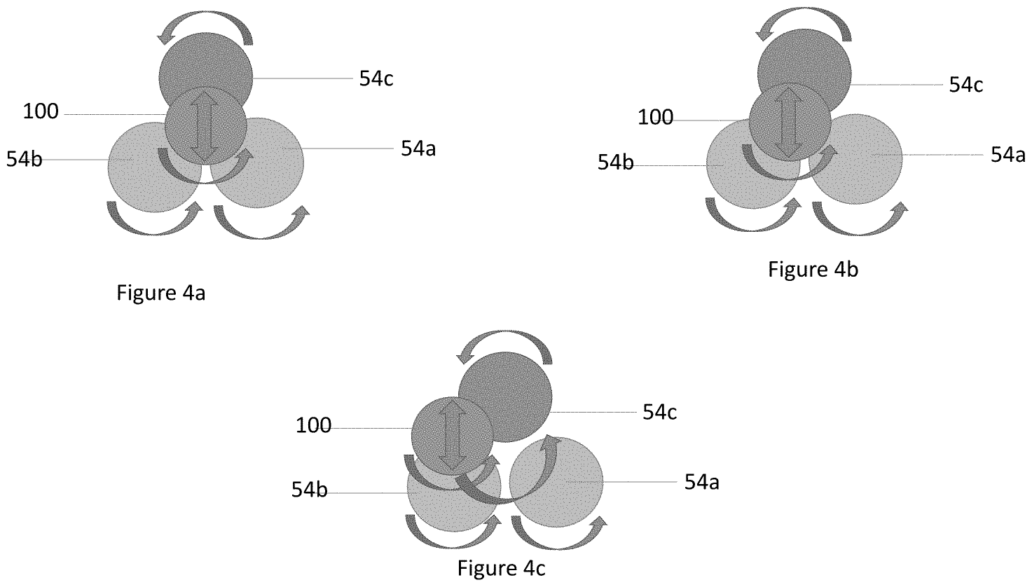

FIG. 4a-c is a top down (plan) view of the polishing pads 54a-c, each supported on an individual platen 52 dedicated thereto. The platens 52 here are positioned adjacent to each other around a center axis. Whereas here three platens are employed, they are spaced about a center point of the three platens at 120° degrees of separation with respect to one another. Each platen 52 rotates about the center of the pad receiving surface thereof on its own center axis. In a first embodiment shown in FIG. 4A, the individual platens 52, and thus the pads 54a-c thereon, are being rotated, and the polishing heads sweeps thereover in a straight line path. The residence time of the polishing head 100 over each of the pads 54a-c during the linear sweep of a substrate head against each of the polishing pads 54a-c is calculated to ensure that all of the polished surface of the substrate spends the same amount of time in contact with the same circumferential locations of a pad 54 as all other polished surfaces of that substrate with that pad, herein equal residence time. However, the amount of time that the polished surface of the substrate is in contact with different ones of the pads can be different, or the same. Here, the substrate can be positioned and engage in relative motion with, only one of the polishing pads, or with any two of the polishing pads 54a-c simultaneously, or withal three of the polishing pads 5a-c simultaneously. The substrate head 110 moves the substrate 40 on a linear axis to position the surface of the substrate being polished to the opposite extremes of the outer perimeter of the platens 52. Simultaneously, the polishing head rotates the substrate about a point at the center of the polished surface thereof.

In another embodiment shown in FIG. 4B, the linear sweep axis of a substrate head 110 positioning a substrate 40 on the surface of the multiple polishing pads 54, here three polishing pads 54a-c, is aligned off center of the three polishing pads 54a. The substrate head 110 moves the substrate 40 on a linear axis to opposite extremes of the outer perimeter of the platens 52. Simultaneously, the polishing head spins the substrate on its own center axis.

In another embodiment shown in FIG. 4C, the sweep path of a substrate head 110 positioning a substrate 40 on the surface of the multiple polishing pads 54a-c, here three polishing pads 54a-c, is orbital. In other words, the center of the polished surface of the substrate follows a circular, elliptical, or polygonal path across the different polishing pads 54a as the substrate itself rotates about the center of the polished surface thereof.

In each of FIGS. 4a to 4C, where each of the polishing pads has different properties, different effects can be performed on the polishing surface of the substrate. For example, if one pad 54a is configured for bulk removal of metal, one pad 54b for less aggressive material removal, and a third pad 54c for even less aggressive material removal of the same material, when the substrate is moving under pressure against the first pad 54a, a fairly rough surface may be produced. When it is polished against the second pad 54b, that roughness can be reduced, and when polished against the third pad, a fairly smooth material surface can be generated. Here, it is contemplated that the substrate will continuously move among and against the three pads for polishing removal of the surface material thereon.

In another aspect, the different platens 52 having different pad 54a-c materials can be used differently, including varying of the residence time of the polished surface of the substrate across the polished surface. For example, the pad 54a can be configured for bulk material removal, the pad 54b for removal of an underlying barrier layer material, and pad 54c for buffing and removal of residual barrier layer material. When the substrate is being polished on pad 54a, the bulk material overlying the field can become removed in circumferential areas of the substrate. These regions can be preferentially polished on the pad 54b, to remove the exposed barrier layer materials, while continuing to remove the bulk layer from other areas of the polished surface, particularly where the bulk material is removed toward the outer circumference of the substrate at a faster rate than radially inwardly thereof. Here, the outer circumferential portion of the substrate can be polished on the platen 52b to remove the barrier while the portions radially inwardly thereof is polished to remove the remaining bulk layer thereon. Then, the substrate can be moved to buff the outer circumferential of the polishing surface while the inner circumferential portion of the polishing surface is biased against the pad 54b for barrier layer material. Additionally, different slurries are used, based on the materials being polished. Combinations of this paradigm where the substrate polishing surface is contacting different pads 54a-c can be combined with linear oscillation and orbiting of the substrate to obtain a desired polishing result.

The configuration of the polishing station 50b can also be a standalone polisher, where the substrate is polished only on the three pads 54a-c. Alternatively, when employed in the system of FIGS. 1 and 2, the polishing station 50a will commonly perform the bulk overburden removal, for example remove the majority of a metal layer thereon such that portions if an underlying layer, for example a barrier layer, is exposed. Using the above described methods of operation regarding the placement of the substrate with respect to the pads 54a-c, the substrate can be transferred to process station 5ob and moved between the three different pads to remove the remaining bulk material, as well as at least the majority of any underlayer material, before being transferred to the third process station 50c for buffing, followed by removal from the system for cleaning.

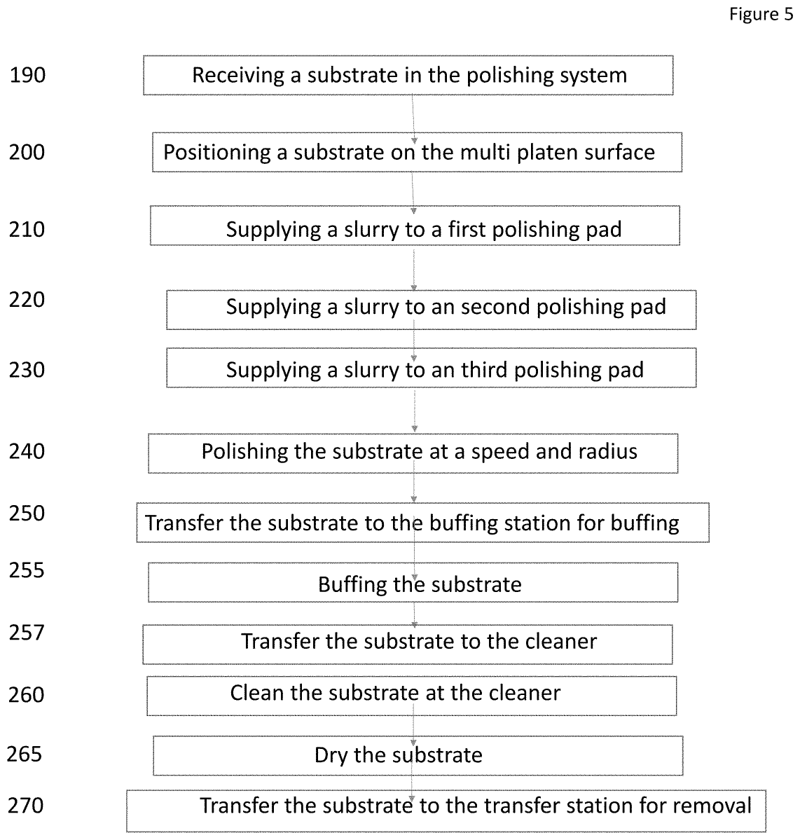

FIG. 5 is a flow chart illustrating one embodiment of a process to remove copper-containing materials in the planarization process described above and barrier layer removal. In a first action, Act 190 a substrate 40 is moved from the loading apparatus 30 into the transfer station 70 using a robot 35 and robot blade attached thereto. The substrate is then chucked into a polishing head 100, at the transfer station 70, and the polishing head holding the substrate 40 therein sequentially moves the substrate to polishing stations 50a, 50b and 50c in that order for polishing or buffing operations at each station. After the polishing head has enabled polishing of the substrate at polishing station 50a at Act 195, the polishing head lifts the substrate of the polishing pad therein, and moves the substrate 40 to the polishing station 50b. Here, the multi-platen configuration of FIG. 3 is provided. The polishing head 100 positions the substrate in contact with the polishing pads 54a-c of the multi-platen polishing station in any desired sequence and residence time paradigm at Act 200. The pressure between the substrate 40 and pad 54-c may be tuned by a user or selected by an automated process. A first polishing composition is supplied to the polishing pad 54a at a first flow rate at Act 210. A second polishing composition is supplied to the polishing pad 54b at a second flow rate at Act 220. A third polishing composition is supplied to the polishing pad 54c at a third flow rate at Act 230. Each of the polishing pads 54a-c may have different roughnesses, thicknesses, and viscosities, and the chemical compositions supplied to each may be different.

In this process sequence, at least a portion of the bulk copper-containing materials is then removed from the surface of the substrate by polishing the substrate 40 against the polishing pads 54a-c in the process station 50b at Act 240. In the polishing process at Act 240, the polishing head 110 positions the substrate in contact with the polishing pads 54a-c in a user selected sequence for a user selected time, and the substrate and the polishing pad rotate with the liquid polishing composition(s) distributed therebetween between to effect chemical and mechanical polishing activity on the substrate. The barrier layer if present is also substantially removed in polishing station 50b. The substrate 40 is them moved by the polishing head 100 to polishing station 50c at Act 250, and buffed against the polishing pad 54 therein at Act 255. At the terminus of the polishing process the substrate 40 is typically removed from contact with the polishing pads 54 and transferred to a cleaner (not shown) at Act 257. During the transfer of the substrate 40, the substrate is rinsed by the rinse head 80, positioned between each station. At the cleaner, a cleaning composition is released to bathe the substrate, thus cleaning the substrate 40 from all debris accumulated during the polishing action in Act 260. The substrate is then rinsed and dried at Act 265, thus drying the substrate 40. To complete the polishing cycle, the substrate 40 is returned to the transfer station 70 for removal from the polishing system 10 at Act 270.

The polishing pads 54 disposed on the substrate are rotated at a rate between about 50 rpms and about 150 rpms for a polishing pad disposed on rotatable platens 5. The substrate disposed in a polishing head 110 is rotated at a rotational speed, for example, between about 50 rpms and about 150 rpms. The rotational speed may be a variable knob selected by the user or automated. Typically, a rotational speed between about 80 rpms and 100 rpms for both the carrier head and the platen, for example 93 rpms and 87 rpms respectively, has been used to remove bulk material from the substrate surface. The polishing article and substrate are generally rotated in the same direction, although they may be rotated in opposite directions. At the carrier head and platen rotational speeds, the substrate is polished with a scanning speed, or relative linear velocity between about 600 mm/second and about 1900 mm/second at the center of the substrate. The scanning speed may be a variable knob selected by the user or automated.

The first polishing action typically provides a first relative linear velocity between about 600 mm/second and about 1900 mm/second, which results in effective removal of bulk conductive materials, and the second polishing step typically provides a second relative linear velocity between about 100 mm/second and about 550 mm/second for effective removal of any residual conductive materials.

The relative linear velocity of the substrate is usually considered the linear velocity at the center of the substrate. For a rotating substrate, the average relative linear velocity typically increases when measured further from the center of the substrate. Additionally, the relative linear velocity of the substrate increases as the substrate is moved from the center of a rotating polishing media. An example of a relative linear velocity at the rotational speeds and rotational speed ratios described herein may produce a linear velocity between about 100 mm/second and about 550 mm/second at the center of a substrate displaced approximately 12.5 cm to 13 cm from the rotating polishing article axis.

Polishing may be enhanced by delivering a polishing composition in the first step at a flow rate of about 200 ml/min or greater and delivering the polishing composition at a flow rate between about 10 ml/min and about 50 ml/min during the second polishing step.

Bulk conductive material is broadly defined herein as conductive material deposited on the substrate in an amount sufficient to fill features formed on the substrate surface and cover about 25% or more of the surface area of the substrate. Bulk material is generally deposited to a sufficient thickness to cover the entire substrate surface above a dielectric layer. Bulk conductive material may include copper-containing material, for example, copper, copper alloys, and/or doped copper.

Residual or remaining conductive material is broadly defined as any conductive material that covers about 25% or less of the surface area of the substrate. The residual material is generally present in an amount covering between about 5% and about 10% of the surface area of a substrate after one or more polishing process steps using abrasive containing or abrasive-free polishing compositions with conventional polishing pads to remove bulk material from the substrate surface. Residual conductive material may include copper-containing material, for example, copper, copper alloys, copper oxide, and/or doped copper.

Substrate surface that may be polished by the processes described herein having bulk conductive material formed thereon are generally formed by having a dielectric layer with feature definitions formed therein, depositing a barrier layer generally on the dielectric layer and in the feature definitions, and depositing the conductive material, such as the copper-containing material, in sufficient amounts to fill the feature definitions formed therein.

As used throughout this disclosure, the phrase “copper-containing material”, “copper” and the symbol Cu are intended to encompass high purity elemental copper as well as doped copper and copper-based alloys, e.g., doped copper and copper-based alloys containing at least about 80 wt. % copper. The barrier layer material includes tantalum, tantalum nitride, and derivatives thereof, such as tantalum silicon nitride. The invention described herein also contemplates the use of other barrier materials known or unknown that may be used as a barrier with conductive materials known or unknown, such as copper, that may be used if forming semiconductor features.

The dielectric layer can comprise any of various dielectric materials known or unknown that may be employed in the manufacture of semiconductor devices. For example, dielectric materials, such as silicon dioxide, phosphorus-doped silicon glass (PSG), boron-phosphorus-doped silicon glass (BPSG), and carbon-doped silicon dioxide, can be employed. The dielectric layer can also comprise low dielectric constant materials, including fluoro-silicon glass (FSG), polymers, such as polymides, and carbon-containing silicon oxides, such as Black Diamond™, available from Applied Materials, Inc. of Santa Clara, Calif. The openings are formed in interlayer dielectrics by conventional photolithographic and etching techniques. The invention also contemplates the use of dielectric materials, known or unknown that may be used as dielectric layers in semiconductor fabrication.

While the process described herein illustrates polishing the substrate on three platens, the invention contemplates polishing the substrate by the process described herein on apparatus having two, four, or multiple platens. Additionally, while the following processing parameters are generally described for polishing 200 mm substrates, the invention contemplates modifying processing parameters to satisfy the requirements for polishing substrates of different sizes, such as 300 mm substrates, and polishing on various apparatus, such as orbital motion polishing apparatus. The process described below should be considered illustrative, and should not be construed or interpreted as limiting the scope of the invention.

What is claimed is:

1. A substrate polishing apparatus, comprising:
a processing station comprising:
a plurality of polishing platens having a polishing pad thereon, and
a substrate support configured to hold a substrate therein, wherein the substrate support is positionable to simultaneously position a substrate supported therein against polishing pads on at least two of the plurality of polishing platens.

2. The substrate polishing apparatus of claim 1, wherein the substrate support is positionable to simultaneously position a substrate supported therein against the polishing pads on three polishing platens.

3. The substrate polishing apparatus of claim 2, wherein the substrate support is moveable in a straight line path.

4. The substrate polishing apparatus of claim 2, wherein the substrate support is moveable in an orbital path.

5. The substrate polishing apparatus of claim 1, wherein the polishing pads on at least two of the polishing platens have different material properties.

6. The substrate polishing apparatus of claim 2, wherein the polishing pads on the three polishing platens each have a different polishing pad having at least one property different than that of the other polishing pads.

7. The substrate polishing apparatus of claim 2, wherein the polishing pads on two of the polishing platens have the same material properties.

8. The substrate polishing apparatus of claim 1, wherein the processing station comprising a plurality of polishing platens having a polishing pad thereon, the polishing platens and a substrate support configured to hold a substrate therein, wherein a substrate support head is positionable to simultaneously position a substrate supported therein against polishing pads on at least two of the plurality of polishing platens is a first processing station; and
the polishing apparatus further comprises a second polishing station having at least one polishing platen and a polishing pad thereon, wherein the substrate support is moveable from the first process station to position a substrate polished in the first process station to be polished against the polishing pad in the second polishing station.

9. A method for substrate polishing, comprising:
providing a processing station having a plurality of polishing platens therein, each having a polishing pad thereon,
providing a substrate support configured to hold a substrate therein, wherein
positioning the substrate support to position a substrate supported therein against the polishing pads on at least two of the plurality of polishing platens simultaneously;
and polishing the substrate simultaneously on the two polishing pads.

10. The method of claim 9, wherein the substrate support is positionable to position a substrate supported therein against the polishing pads on three polishing platens simultaneously.

11. The method of claim 10, wherein the substrate support is moveable in a straight line path.

12. The method of claim 10, wherein the substrate support head is moveable in an orbital path.

13. The method of claim 9, wherein the polishing pads on at least two of the polishing platens have different material properties.

14. The method of claim 10, wherein the polishing pads on the three polishing plates each have a different polishing pad having at least one property different than that of the other polishing pads.

15. The method of claim 10, wherein the polishing pads on two of the polishing platens have the same material properties

16. The method of claim 9, wherein the plurality of polishing pads having a polishing pad thereon, the polishing platens and a substrate support configured to hold a substrate therein, wherein the substrate support head is positionable to simultaneously position a substrate supported therein against polishing pads on at least two of the plurality of polishing platens is a first processing station;
providing a second polishing station having at least one polishing patent and a polishing pad thereon, wherein
the substrate support is moveable from the first process station to position a substrate polished in the first process station to be polished against the polishing pad in the second polishing station.

17. A polishing apparatus, comprising:
a first polishing station;
a second polishing station; and
a substrate support configured to support a substrate therein in facing relationship to a polishing station and moveable to position a substrate supported therein at the first polishing station and the second polishing station; and
at least a first and a second rotatable polishing platen disposed in one of the first polishing station and the second polishing station and configured to support a polishing pad thereon, the substrate support positionable to engage a substrate supported therein against a polishing pad on the first polishing platen and simultaneously against a polishing pad on the second polishing platen.

18. The polishing apparatus of claim 17, wherein the first polishing station includes a single polishing platen to support a polishing pad therein, and
the substrate support is positionable to engage a substrate supported therein against a polishing pad on the single platen in the first polishing station.

19. The polishing apparatus of claim 17, further comprising a third polishing station, wherein the third polishing station includes a single polishing platen to support a buffing pad therein, and
the substrate support is positionable to engage a substrate supported therein against the buffing pad on the single platen in the third polishing station.

20. The polishing apparatus of claim 17, wherein the at least a first and a second rotatable polishing platen disposed in one of the first polishing station and the second polishing station are rotatable.
